(19) United States
(12) Patent Application Publication
(10) Pub. No.: US 2023/0361142 A1
(43) Pub. Date: Nov. 9, 2023

(54) IMAGE SENSOR

(71) Applicant: Samsung Electronics Co., Ltd., Suwon-si (KR)

(72) Inventors: Hyeyeon PARK, Suwon-si (KR); Hyungkeun GWEON, Suwon-si (KR); Bumsuk KIM, Suwon-si (KR); Jieun KIM, Suwon-si (KR); Keo-Sung PARK, Suwon-si (KR); Yun Ki LEE, Suwon-si (KR); Hajin LIM, Suwon-si (KR); Taeksoo JEON, Suwon-si (KR); Jaesung HUR, Suwon-si (KR)

(73) Assignee: Samsung Electronics Co., Ltd., Suwon-si (KR)

(21) Appl. No.: 18/170,652

(22) Filed: Feb. 17, 2023

(30) Foreign Application Priority Data
May 3, 2022 (KR) 10-2022-0055033
Aug. 1, 2022 (KR) 10-2022-0095589

(51) Int. Cl. H01L 27/146

(52) U.S. Cl. CPC H01L 27/1463; H01L 27/14627; H01L 27/14636; H01L 27/14621

(57) ABSTRACT

Disclosed is an image sensor including a first substrate that has a first surface and a second surface opposite to the first substrate and including a pixel array region and an edge region, an antireflection structure on the second surface, a pixel separation part in the first substrate and separating pixels from each other, and a microlens array on the antireflection structure. The antireflection structure includes a first dielectric layer, a titanium oxide layer, a second dielectric layer, and a third dielectric layer that are sequentially stacked. The first dielectric layer, the second dielectric layer, and the third dielectric layer include different materials from each other. On the edge region, the third dielectric layer penetrates the second dielectric layer and the titanium oxide layer to contact with the first dielectric layer.

### CROSS-REFERENCE TO RELATED APPLICATIONS

This U.S. nonprovisional application claims priority under 35 U.S.C. § 119 to Korean Patent Applications No. 10-2022-0055033 filed on May 3, 2022 and No. 10-2022-0095589 filed on Aug. 1, 2022 in the Korean Intellectual Property Office, the disclosures of which are hereby incorporated by reference in their entirety.

### BACKGROUND

The present inventive concepts relate to image sensors.

An image sensor is a semiconductor device to transforms optical images into electrical signals. The image sensor may be classified into a charge coupled device (CCD) type and a complementary metal oxide semiconductor (CMOS) type. The CIS (CMOS image sensor) is a short for the CMOS type image sensor. The CIS may include a plurality of two-dimensionally arranged pixels. Each of the pixels includes a photodiode (PD). The photodiode serves to transform an incident light into an electrical signal.

### SUMMARY

Some example embodiments of the present inventive concepts provide image sensors capable of achieving sharp images.

The object of the present inventive concepts is not limited to the mentioned above, and other objects which have not been mentioned above will be clearly understood to those skilled in the art from the following description.

According to some example embodiments of the present inventive concepts, an image sensor may include a first substrate that has a first surface and a second surface opposite to the first substrate, the first substrate including a pixel array region and an edge region; an antireflection structure on the second surface; a pixel separation part in the first substrate, the pixel separation part separating pixels from each other; and a microlens array on the antireflection structure. The antireflection structure may include a first dielectric layer, a titanium oxide layer, a second dielectric layer, and a third dielectric layer that are sequentially stacked. The first dielectric layer, the second dielectric layer, and the third dielectric layer may include different materials from each other. On the edge region, the third dielectric layer may penetrate the second dielectric layer and the titanium oxide layer to contact with the first dielectric layer.

According to some example embodiments of the present inventive concepts, an image sensor may include a first substrate that has a first surface and a second surface opposite to the first substrate, the first substrate including a pixel array region and an edge region; an antireflection structure on the second surface; a pixel separation part on the first substrate, the pixel separation part separating pixels from each other; a color filter on the antireflection structure; a microlens array on the color filter; a first interlayer dielectric layer on the first surface of the first substrate; a first interconnection layer in the first interlayer dielectric layer; a second interlayer dielectric layer below the first interlayer dielectric layer; a second interconnection layer in the second interlayer dielectric layer; a second substrate below the second interlayer dielectric layer; a first contact on the second surface of the first substrate on the edge region; and a second contact on the edge region, the second contact penetrating the first substrate, the first interlayer dielectric layer, and a portion of the second interlayer dielectric layer to contact with the second interconnection layer. The antireflection structure may include a first dielectric layer, a titanium oxide layer, a second dielectric layer, and a third dielectric layer that are sequentially stacked. The first dielectric layer, the second dielectric layer, and the third dielectric layer may include different materials from each other. Between the first contact and the second contact, the third dielectric layer may penetrate the second dielectric layer and the titanium oxide layer to contact with the first dielectric layer.

According to some example embodiments of the present inventive concepts, an image sensor may include a first substrate that has a first surface and a second surface opposite to the first substrate, the first substrate including a pixel array region and an edge region; an antireflection structure on the second surface; a pixel separation part in the first substrate, the pixel separation part separating pixels from each other; and a microlens array on the antireflection structure. The antireflection structure may include a first dielectric layer, a titanium oxide layer, a second dielectric layer, and a third dielectric layer that are sequentially stacked. The first dielectric layer, the second dielectric layer, and the third dielectric layer may include different materials from each other. A groove may be on the edge region in the titanium oxide layer and the second dielectric layer. The first dielectric layer may be exposed on a bottom surface of the groove. The third dielectric layer may conformally cover a lateral surface and the bottom surface of the groove. When viewed in plan, the groove may surround the pixel array region.

### BRIEF DESCRIPTION OF THE DRAWINGS

FIG. 1 illustrates a block diagram showing an image sensor according to some example embodiments of the present inventive concepts.

FIG. 2 illustrates a circuit diagram showing an active pixel sensor array of an image sensor according to some example embodiments of the present inventive concepts.

FIG. 3 illustrates a plan view showing an image sensor according to some example embodiments of the present inventive concepts.

FIG. 4 illustrates a cross-sectional view taken along line A-A′ of FIG. 3.

FIG. 5 illustrates a partial plan view showing an image sensor of FIG. 3.

FIG. 6 illustrates a plan view showing a via array disposed on a via region of FIG. 3.

FIG. 7A illustrates an enlarged view showing section P2 of FIG. 4.

FIG. 7B illustrates an enlarged view showing section P1 of FIG. 4.

FIGS. 8A to 8H illustrate cross-sectional views showing a method of fabricating an image sensor having the cross-section of FIG. 4.

FIG. 9 illustrates a cross-sectional view taken along line A-A′ of FIG. 3.

FIG. 10 illustrates a cross-sectional view showing an image sensor according to some example embodiments of the present inventive concepts.

FIG. 11A illustrates an enlarged view showing section P2 of FIG. 10.

FIG. 11B illustrates an enlarged view showing section P1 of FIG. 10.

FIG. 12 illustrates a cross-sectional view showing an image sensor according to some example embodiments of the present inventive concepts.

### DETAILED DESCRIPTION

Some example embodiments of the present inventive concepts will now be described in detail with reference to the accompanying drawings to aid in clearly explaining the present inventive concepts.

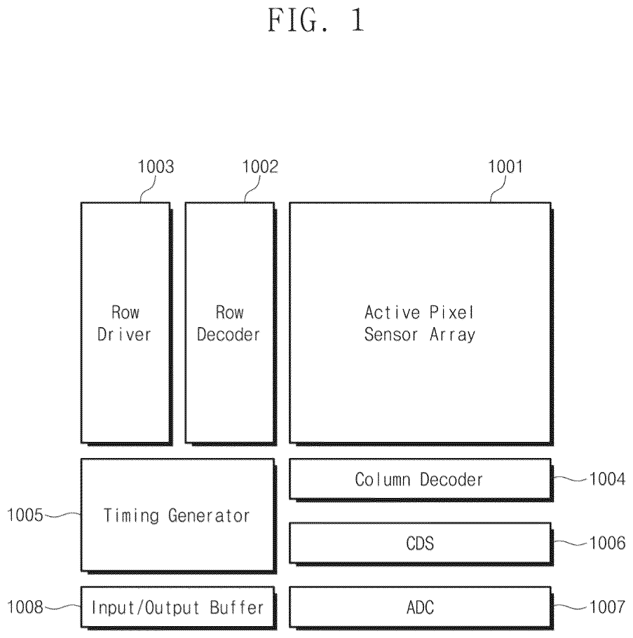

FIG. 1 illustrates a block diagram showing an image sensor according to some example embodiments of the present inventive concepts.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of two-dimensionally arranged unit pixels, each of which is configured to convert optical signals into electrical signals. The active pixel sensor array 1001 may be driven by a plurality of driving signals such as a pixel selection signal, a reset signal, and a charge transfer signal from the row driver 1003. The correlated double sampler 1006 may be provided with the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for respective rows.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then output the converted digital signals.

The input/output buffer 1008 may latch the digital signals and then sequentially output the latched digital signals to an image signal processing unit (not shown) in response to the decoded result obtained from the column decoder 1004.

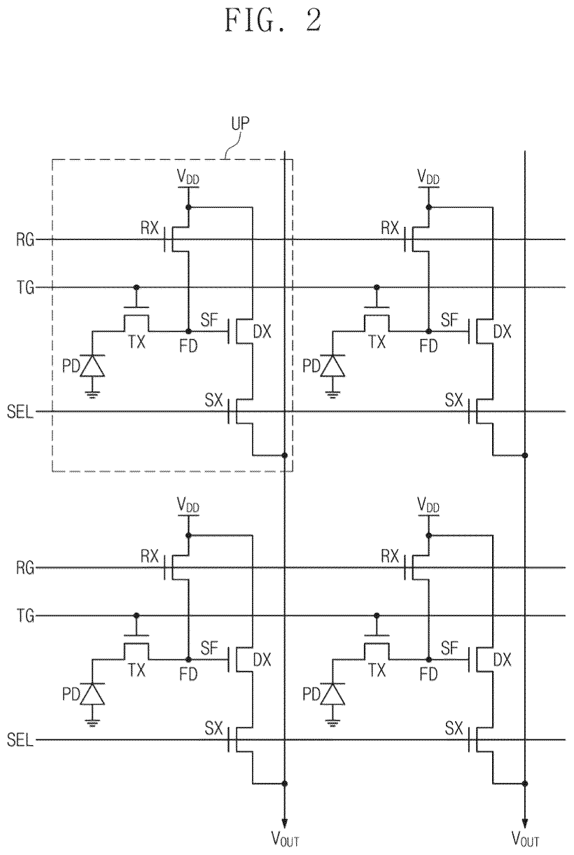

FIG. 2 illustrates a circuit diagram showing an active pixel sensor array of an image sensor according to some example embodiments of the present inventive concepts.

Referring to FIGS. 1 and 2, the active pixel sensor array 1001 may include a plurality of unit pixels PX, which unit pixels PX may be arranged in a matrix shape. Each unit pixel UP may include a transfer transistor TX. Each unit pixel UP may further include logic transistors RX, SX, and DX. The logic transistors RX, SX, and DX may include a reset transistor RX, a selection transistor SX, and a source follower transistor DX. The transfer transistor TX may include a transfer gate electrode TG. Each of the unit pixels PX may further include a photoelectric conversion element PD and a floating diffusion region FD. The logic transistors RX, SX, and DX may be shared by a plurality of unit pixels UP.

The photoelectric conversion element PD may create and accumulate photo-charges in proportion to an amount of externally incident light. The photoelectric conversion element PD may include a photodiode, phototransistor, a photogate, a pinned photodiode, or a combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage V_{DD}. When the reset transistor RX is turned on, the floating diffusion region FD may be supplied with the power voltage V_{DD} connected to the source electrode of the reset transistor RX. Accordingly, when the reset transistor RX is turned on, the charges accumulated in the floating diffusion region FD may be exhausted and thus the floating diffusion region FD may be reset.

The source follower transistor DX including a source follower gate electrode SF may serve as a source follower buffer amplifier. The source follower transistor DX may amplify a variation in electrical potential of the floating diffusion region FD and may output the amplified electrical potential to an output line V_{OUT}.

The selection transistor SX including a selection gate electrode SEL may select each row of the unit pixel P to be readout. When the selection transistor SX is turned on, the power voltage V_{DD} may be applied to a drain electrode of the source follower transistor DX.

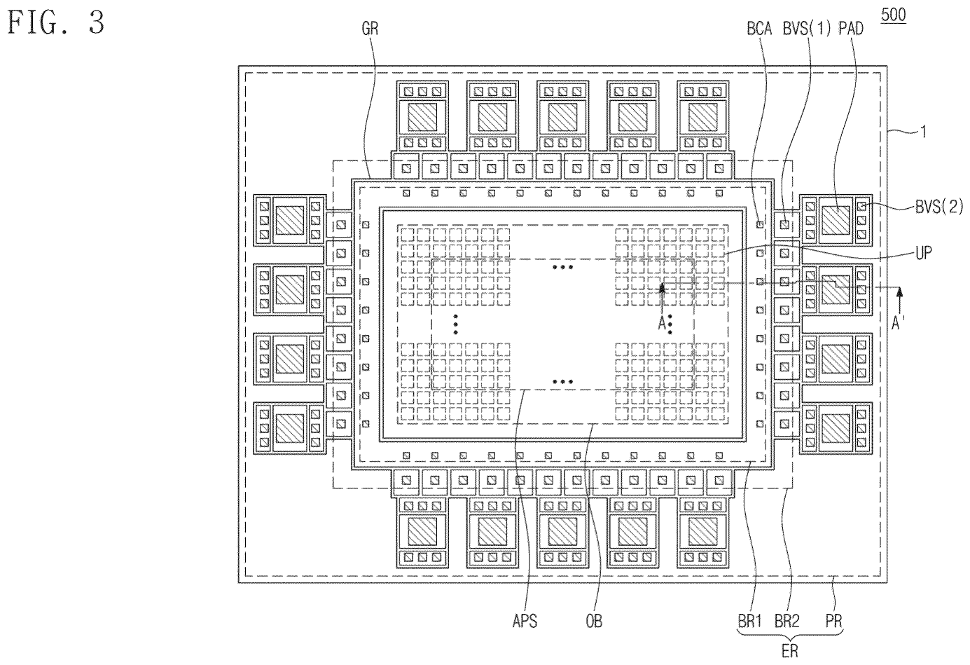

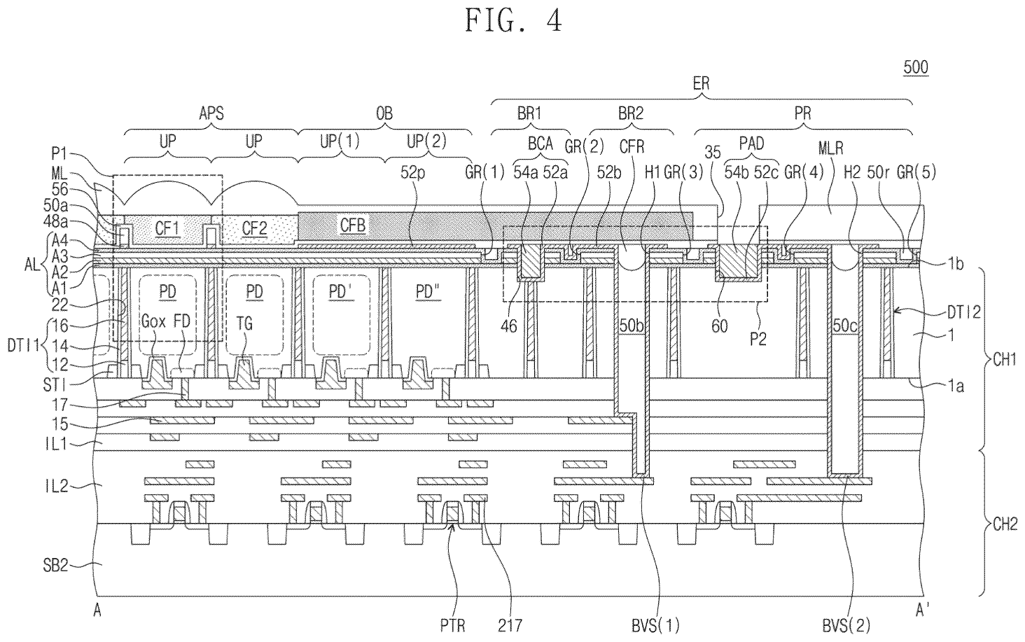

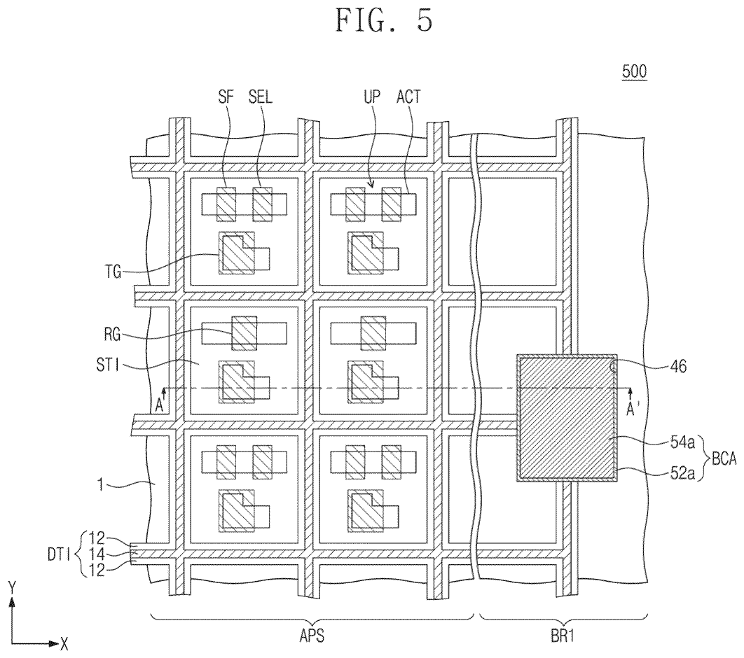

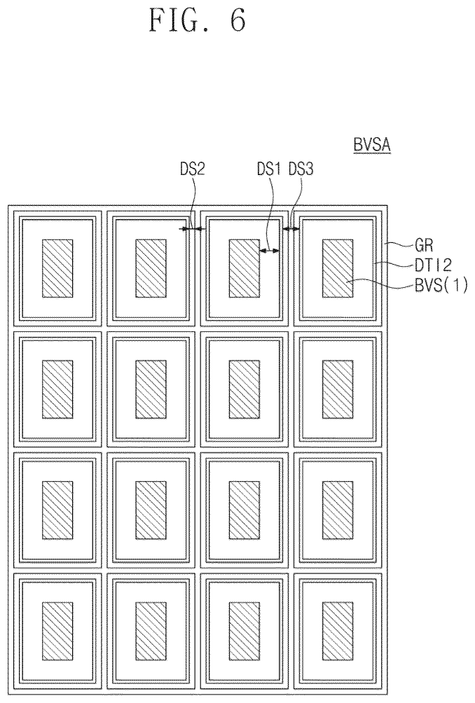

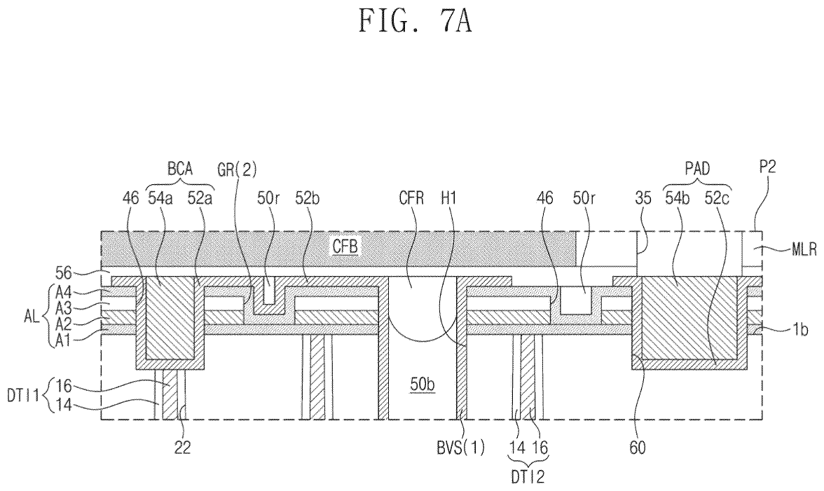

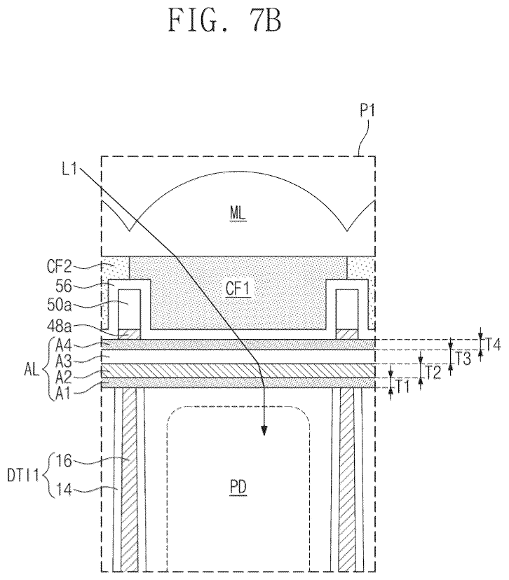

FIG. 3 illustrates a plan view showing an image sensor according to some example embodiments of the present inventive concepts. FIG. 4 illustrates a cross-sectional view taken along line A-A′ of FIG. 3. FIG. 5 illustrates a partial plan view showing an image sensor of FIG. 3. FIG. 6 illustrates a plan view showing a via array disposed on a via region of FIG. 3. FIG. 7A illustrates an enlarged view showing section P1 of FIG. 4. FIG. 7B illustrates an enlarged view showing section P2 of FIG. 4.

Referring to FIGS. 3 and 4, an image sensor 500 according to some example embodiments of the present inventive concepts may have a structure in which first and second sub-chips CH1 and CH2 are bonded to each other. The first sub-chip CH1 may be disposed on the second sub-chip CH2. The first sub-chip CH1 may include a first substrate 1. The first substrate 1 may be, for example, a monocrystalline silicon wafer, a silicon epitaxial layer substrate, and/or a silicon-on-insulator (SOI) substrate. The first substrate 1 may be doped with impurities having a first conductivity type. For example, the first conductivity type may be a p-type. The first substrate 1 may have a front surface 1a and a rear surface 1b that are opposite to each other. In this description, the front surface 1a may be called a first surface, and the rear surface 1b may be called a second surface. The first substrate 1 may include a pixel array region APS, an optical black region OB, and an edge region ER.

The pixel array region APS and the optical black region OB may each include a plurality of unit pixels UP. The optical black region OB may surround the pixel array region APS. The optical black region OB may surround the pixel array region APS and the optical black region OB. The edge region ER may include a contact region BR1, a via region BR2, and a pad region PR. The via region BR2 may be positioned between the contact region BR1 and the pad region PR. The pad region PR may be positioned on an outermost section of the edge region ER. In this description, the term “via” may be called “contact.” Alternatively, the term “contact” may be called “via.”

On the pixel array region APS and the optical black region OB, the first substrate 1 may have therein a first pixel separation part DTI1 that is disposed to separate and/or limit the unit pixels UP. The first pixel separation part DTI1 may extend to the contact region BR1 of the edge region ER. The first pixel separation part DTI1 may have a network shape when viewed in plan.

On the edge region ER, the first substrate 1 may be provided on its rear surface 1b with backside contacts BCA, backside vias BVS, and backside conductive pads PAD. Referring to FIGS. 4 and 6, when viewed in plan, a second pixel separation part DTI2 may surround each of the backside vias BVS. The backside vias BVS may include first backside vias BVS(1) and second backside vias BVS(2). One or more of column and row signals may be transferred through the backside vias BVS between the first and second sub-chips CH1 and CH2.

Each of the first and second pixel separation parts DTI1 and DTI2 may be positioned in a deep trench 22 that is formed to extend from the front surface 1a toward the rear surface 1b of the first substrate 1. Each of the first and second pixel separation parts DTI1 and DTI2 may be a front-side deep trench isolation (FDTI). Each of the first and second pixel separation parts DTI1 and DTI2 may include a buried dielectric pattern 12, a separation dielectric pattern 14, and a separation conductive pattern 16. The buried dielectric pattern 12 may be interposed between the separation conductive pattern 16 and a first interlayer dielectric layer IL1 which will be discussed below. The separation dielectric pattern 14 may be interposed between the separation conductive pattern 16 and the first substrate 1 and between the buried dielectric pattern 12 and the first substrate 1.

The buried dielectric pattern 12 and the separation dielectric pattern 14 may be formed of a dielectric material whose refractive index is different from that of the first substrate 1. The buried dielectric pattern 12 and the separation dielectric pattern 14 may include, for example, silicon oxide. The separation conductive pattern 16 may be spaced apart from the first substrate 1. The separation conductive pattern 16 may include an impurity-doped polysilicon layer or an impurity-doped silicon-germanium layer. For example, one of boron, phosphorus, and arsenic may be adopted as impurities doped into the polysilicon or silicon-germanium layer. Alternatively, the separation conductive pattern 16 may include a metal layer.

As shown in FIG. 4, each of the first and second pixel separation parts DTI1 and DTI2 may have a width that decreases in a direction from the front surface 1a toward the rear surface 1b of the first substrate 1. For example, the first and second pixel separation parts DTI1 and DTI2 may have greater widths at the front surface 1a than at the rear surface 1b, and the decreasing widths may be linear, curved, and/or the like. In this description, the language “width” may be replaced with the language “thickness.” The second pixel separation part DTI2 may be called “substrate isolation part.”

The first substrate 1 may have therein photoelectric conversion elements PD on corresponding unit pixels UP. The photoelectric conversion elements PD may be doped with impurities having a second conductivity type opposite to the first conductivity type. The second conductivity type may be, for example, an n-type. The n-type impurities doped in the photoelectric conversion element PD and the p-type impurities doped in the first substrate 1 therearound may constitute a PN junction to provide a photodiode.

The first substrate 1 may have therein device isolation parts STI adjacent to the front surface 1a. The first pixel separation parts DTI1 may penetrate the device isolation part STI. On each unit pixel UP, the device isolation parts STI may limit active sections (see ACT of FIG. 5) adjacent to the front surface 1a. The active sections ACT may be provided for the transistors TX, RX, DX, and SX of FIG. 2.

Referring to FIG. 4, on each unit pixel UP, a transfer gate electrode TG may be disposed on the front surface 1a of the first substrate 1. A portion of the transfer gate electrode TG may extend into the first substrate 1. The transfer gate electrode TG may have a vertical type. Alternatively, the transfer gate electrode TG may be a planar type that is flat without extending into the first substrate 1. A gate dielectric layer Gox may be interposed between the transfer gate electrode TG and the first substrate 1. A floating diffusion region FD may be disposed in the first substrate 1 on one side of the transfer gate electrode TG. The floating diffusion region FD may be doped with impurities having, for example, the second conductivity type.

The image sensor 500 may be a backside illumination image sensor. The first substrate 1 may receive light that is incident through the rear surface 1b of the first substrate 1. The PN junction may create electron-hole pairs from the incident light. These created electrons may move toward the photoelectric conversion elements PD. When a voltage is applied to the transfer gate electrode TG, the electrons may move toward the floating diffusion region FD.

As shown in FIG. 5, on one of the unit pixels UP, the front surface 1a may be provided thereon with a reset gate electrode RG adjacent to the transfer gate electrode TG. On another of the unit pixels UP, the front surface 1a may be provided thereon with a source follower gate SF and a selection gate electrode SEL that are adjacent to the transfer gate electrode TG. The gate electrodes TG, RG, SF, and SEL may correspond to gate electrodes of the transistors TX, RX, DX, and SX, respectively, of FIG. 2. The gate electrodes TG, RG, SF, and SEL may overlap the active sections ACT. In some example embodiments, the reset transistor RX, the selection transistor SX, and the source follower transistor DX may be shared by two neighboring unit pixels UP.

A first unit pixel UP(1) and a second unit pixel UP(2) may be disposed on the optical black region OB of the first substrate 1. On the first unit pixel UP(1), a black photoelectric conversion element PD′ may be provided in the first substrate 1. On the second unit pixel UP(2), a dummy region PD″ may be provided in the first substrate 1. The black photoelectric conversion element PD′ may be doped with impurities having, for example, the second conductivity type different from the first conductivity type. The second conductivity type may be, for example, an n-type. The pixel array region APS may include a plurality of unit pixels UP. The black photoelectric conversion element PD′ may have a similar structure to that of the photoelectric conversion element PD, but may not perform the same operation (e.g., conversion of light into electrical signals) as that of the photoelectric conversion element PD. The dummy region PD″ may not be doped with impurities. The dummy region PD″ may generate signals that are used as information to remove subsequent process noise.

The first sub-chip CH1 may further include first interlayer dielectric layers IL1 disposed on the front surface 1a. The first interlayer dielectric layers IL1 may be formed of a multiple layer including at least one selected from a silicon oxide layer, a silicon nitride layer, a silicon oxynitride layer, and a porous low-k dielectric layer. The first interlayer dielectric layers IL1 may be provided with first wiring lines 15 therebetween or therein. The floating diffusion region FD may be connected through first contact plugs 17 to the first wiring lines 15. On the pixel array region APS, the first contact plug 17 may penetrate one (e.g., lowermost one) of the first interlayer dielectric layers IL1 that is most adjacent to the front surface 1a.

The second sub-chip CH2 may include a second substrate SB2, peripheral transistors PTR disposed on the second substrate SB2, and second interlayer dielectric layers IL2 that cover the peripheral transistors PTR. The second interlayer dielectric layers IL2 may be provided with second wiring lines 217 therein. The second sub-chip CH2 may include circuits for storing electrical signals generated from the first sub-chip CH1.

Referring to FIGS. 4, 7A, and 7B, an antireflection structure AL may be disposed on the rear surface 1b of the first substrate 1. The antireflection structure AL may include a first dielectric layer A1, a titanium oxide layer A2, a second dielectric layer A3, and a third dielectric layer A4 that are sequentially stacked. The first dielectric layer A1, the second dielectric layer A3, and the third dielectric layer A4 may include different materials from each other. For example, the first dielectric layer A1 may include aluminum oxide, the second dielectric layer A3 may include silicon oxide, and the third dielectric layer A4 may include hafnium oxide.

In this description, the first dielectric layer A1 may be called “a first antireflection layer”, the titanium oxide layer A2 may be called “a second antireflection layer”, the second dielectric layer A3 may be called “a third antireflection layer”, and the third dielectric layer A4 may be called “a fourth antireflection layer.”

The first substrate 1 may have a first refractive index n1, the first dielectric layer A1 may have a second refractive index n2, the titanium oxide layer A2 may have a third refractive index n3, and the second dielectric layer A3 may have a fourth refractive index n4. An average, (n2+n3)/2, of the second refractive index n2 and the third refractive index n3 may be less than the first refractive index n1 and greater than the fourth refractive index n4. For example, the first refractive index n1 may range from about 4.0 to about 4.4. The second refractive index n2 may range from about 2.0 to about 3.0. The third refractive index n3 may range from about 2.2 to about 2.8. The fourth refractive index n4 may range from about 1.0 to about 1.9.

As shown in FIG. 7B, the first dielectric layer A1 may have a first thickness T1, the titanium oxide layer A2 may have a second thickness T2, the second dielectric layer A3 may have a third thickness T3, and the third dielectric layer A4 may have a fourth thickness T4. In some example embodiments, the thicknesses T1, T2, T3, and T4 may be different from one another, and in some example embodiments, the thicknesses T1, T2, T3, and T4, or some subset thereof, may be the same or similar, e.g., all of the thicknesses T1, T2, T3, and T4, or only thicknesses T1 and T4. In some example embodiments, the second thickness T2 may be less than the third thickness T3 and greater than each of the first thickness T1 and the fourth thickness T4.

For example, the first thickness T1 may range from about 10 Å to about 100 Å. The second thickness T2 may range from about 100 Å to about 600 Å. The third thickness T3 may range from about 600 Å to about 900 Å. The fourth thickness T4 may range from about 20 Å to about 200 Å.

As shown in FIG. 7B, a relationship between refractive indices and/or thicknesses may allow that light L1 incident on a subsequently described microlens ML is refracted and penetrates through a multi-layered structure of the antireflection structure AL and then is appropriately incident on the photoelectric conversion element PD. Accordingly, the image sensor 500 may have increased light-receiving efficiency and sharp image quality.

In addition, in the image sensor 500 according to the present inventive concepts, the antireflection structure AL may include the titanium oxide layer A2. The titanium oxide layer A2 may entirely reduce reflectivity of all colors, and in particular, may further reduce reflectivity of blue light. Accordingly, a blue color pixel may increase in quantum efficiency (QE).

The first dielectric layer A1 may serve as a negative fixed charge layer. Therefore, it may be possible to reduce the dark current and white spot.

Referring to FIGS. 3, 4, and 7A, on the edge region ER, the third dielectric layer A4 may penetrate the second dielectric layer A3 and the titanium oxide layer A2 to contact with the first dielectric layer A1. The second dielectric layer A3 and the titanium oxide layer A2 may have grooves GR formed therein. The third dielectric layer A4 may conformally cover lateral and bottom surfaces of the grooves GR. When viewed in plan as shown in FIG. 3, the grooves GR may surround the pixel array region APS and the optical black region OB. For example, the grooves GR may partially penetrate the antireflection structure AL, while the trenches 46, 60 may fully penetrate the antireflection structure AL.

Referring to FIGS. 3 and 4, on the contact region BR1, the backside contacts BCA may be disposed on the rear surface 1b of the first substrate 1. On the via region BR2, the first backside vias BVS(1) may be disposed on the rear surface 1b of the first substrate 1. On the pad region PR, the backside conductive pads PAD and the second backside vias BVS(2) may be disposed on the rear surface 1b of the first substrate 1. Several of the second backside vias BVS(2) may form a group, and a plurality of groups may be disposed around corresponding backside conductive pads PAD. An external signal may be input/output through the backside conductive pads PAD. The backside conductive pads PAD may become interfaces of external signals.

As shown in FIG. 3, the grooves GR may surround the backside contacts BCA. The grooves GR may not be interposed between the backside contacts BCA. The grooves GR may surround the first backside vias BVS(1). The grooves GR may surround the backside conductive pads PAD. The grooves GR may simultaneously surround the second backside vias BVS(2) several of which constitute a group. Portions of the grooves GR may be connected to each other.

An arrangement of the first backside vias BVS(1) may be variously changed without being limited to that shown in FIG. 3. For example, as shown in FIG. 6, the first backside vias BVS(1) may constitute a backside via array BVSA on the via region BR2. The first backside vias BVS(1) may be arranged in several columns and rows. The grooves GR may surround the first backside vias BVS(1). As shown in FIG. 6, a first interval DS1 between one first backside via BVS(1) and its adjacent second pixel separation part DTI2 may be greater than a second interval DS2 between the second pixel separation part DTI2 and its adjacent groove GR. Neighboring second pixel separation parts DTI2 may be spaced apart from each other at a third interval DS3. The third interval DS3 may be greater than the second interval DS2 and less than the first interval DS1. For example, the first interval DS1 may range from about 1.5 μm to about 2.5 μm. The second interval DS2 may range from about 0.1 μm to about 0.5 μm. The third interval DS3 may range from about 0.5 μm to about 1.5 μm.

Referring to FIGS. 4 and 7A, the backside contacts BCA, the first backside vias BVS(1), the second backside vias BVS(2), and the backside conductive pads PAD may penetrate the antireflection structure AL and at least a portion of the first substrate 1. The backside contacts BCA may be disposed in a first backside trench 46. The backside contact BCA may include a first conductive pattern 52a and a first metal pattern 54a. The first conductive pattern 52a may conformally cover lateral and bottom surfaces of the first backside trench 46. The first conductive pattern 52a may have a single-layered or multi-layered structure including at least one selected from a titanium layer, a titanium nitride layer, and a tungsten layer. The first metal pattern 54a may include, for example, aluminum. The first metal pattern 54a may fill the first backside trench 46.

The backside contact BCA may be in contact with the separation conductive pattern 16 of the first pixel separation part DTI1. A negative bias may be applied through the backside contact BCA to the separation conductive pattern 16 of the first pixel separation part DTI1. The separation conductive pattern 16 may serve as a common bias line. Therefore, holes possibly present in a surface of the first substrate 1 in contact with the first pixel separation part DTI1 may be trapped to reduce the dark current.

The first backside vias BVS(1) may be disposed in corresponding first holes H1. The first backside vias BVS(1) may penetrate the antireflection structure AL, the first substrate 1, the first interlayer dielectric layers IL1, and a portion of the second interlayer dielectric layer IL2. The first backside vias BVS(1) may connect ones of the first wiring lines 15 to ones of the second wiring lines 217. The first backside vias BVS(1) may conformally cover inner walls and bottom surfaces of the first holes H1. The first backside vias BVS(1) may include the same material and thickness as that of the first conductive pattern 52a. The first backside via BVS(1) may have a single-layered or multi-layered structure including at least one selected from a titanium layer, a titanium nitride layer, and a tungsten layer.

One of the first backside vias BVS(1) may be electrically connected through one of backside connection lines 52b to one of the backside contacts BCA. The backside connection line 52b may be disposed on the antireflection structure AL. The backside connection line 52b may include the same material and thickness as that of the first conductive pattern 52a. The backside connection line 52b may have a single-layered or multi-layered structure including at least one selected from a titanium layer, a titanium nitride layer, and a tungsten layer.

The backside conductive pad PAD may be disposed in a second backside trench 60. The backside conductive pad PAD may include a second conductive pattern 52c and a second metal pattern 54b. The second conductive pattern 52c may conformally cover lateral and bottom surfaces of the second backside trench 60. The second conductive pattern 52c may include the same material and thickness as that of the first conductive pattern 52a. The second conductive pattern 52c may have a single-layered or multi-layered structure including at least one selected from a titanium layer, a titanium nitride layer, and a tungsten layer. The second metal pattern 54b may include, for example, aluminum. The second metal pattern 54b may fill the second backside trench 60.

The second backside vias BVS(2) may be disposed in corresponding second holes H2. The second backside vias BVS(2) may penetrate the antireflection structure AL, the first substrate 1, the first interlayer dielectric layers IL1, and a portion of the second interlayer dielectric layer IL2. The second backside vias BVS(2) may be connected to ones of the second wiring lines 217. Although not shown, the second backside vias BVS(2) may be connected to ones of the first wiring lines 15. The second backside vias BVS(2) may conformally cover inner walls and bottom surfaces of the second holes H2. The second backside vias BVS(2) may include the same material and thickness as that of the first conductive pattern 52a. The second backside via BVS(2) may have a single-layered or multi-layered structure including at least one selected from a titanium layer, a titanium nitride layer, and a tungsten layer. One of the second backside vias BVS(2) may be electrically connected through another of backside connection lines 52b to one of the backside conductive pads PAD.

The grooves GR may include first to fifth grooves GR(1) to GR(5). The first groove GR(1) may be interposed between the optical black region OB and the contact region BR1. The second groove GR(2) may be interposed between the backside contacts BCA and the first backside vias BVS(1). The third groove GR(3) may be interposed between the first backside vias BVS(1) and the backside conductive pads PAD. The fourth groove GR(4) may be interposed between the backside conductive pads PAD and the second backside vias BVS(2). The fifth groove GR(5) may be spaced apart from and disposed on one side of the second backside vias BVS(2).

In the second groove GR(2), one of the backside connection lines 52b may conformally cover a sidewall and a bottom surface of the third dielectric layer A4. In the fourth groove GR(4), another of the backside connection lines 52b may conformally cover a sidewall and a bottom surface of the third dielectric layer A4.

The grooves GR may cut the titanium oxide layer A2. The titanium oxide layer A2 may have conductivity greater than those of other dielectric layers. When the grooves GR are absent, the titanium oxide layer A2 may cause the occurrence of undesired leakage current between the backside contacts BCA, the backside vias BVS, and the backside conductive pads PAD that are adjacent to each other. There may thus be induced an operation error or image quality degradation of an image sensor. In contrast, in the present inventive concepts, because the grooves GR cut the titanium oxide layer A2, an undesired leakage current may be prevented or reduced from being generated between the backside contacts BCA, the backside vias BVS, and the backside conductive pads PAD that are adjacent to each other. Accordingly, it may be possible to prevent or reduce an operation error or image quality degradation of the image sensor 500.

On the edge region ER, a first optical black pattern 52p may be disposed on the antireflection structure AL. The first optical black pattern 52p may include the same material and thickness as that of the first conductive pattern 52a. The first optical black pattern 52p may have a single-layered or multi-layered structure including at least one selected from a titanium layer, a titanium nitride layer, and a tungsten layer.

On the pixel array region APS, light-shield grid patterns 48a may be disposed on the antireflection structure AL. The light-shield grid patterns 48a may be correspondingly provided thereon with low-refractive grid patterns 50a. The light-shield grid pattern 48a and the low-refractive grid pattern 50a may overlap the first pixel separation part DTI1 and may have a grid shape when viewed in plan. The light-shield grid pattern 48a may include, for example, at least one selected from titanium and titanium nitride. The low-refractive grid patterns 50a may have the same thickness and the same organic material. The low-refractive grid pattern 50a may have a refractive index less than those of color filters CF1 and CF2 which will be discussed below. For example, the low-refractive grid pattern 50a may have a refractive index equal to or less than about 1.3. The light-shield grid pattern 48a and the low-refractive grid pattern 50a may prevent or reduce the crosstalk between neighboring unit pixels UP.

The grooves GR may be provided with and filled with low-refractive residual patterns 50r. A first low-refractive protection pattern 50b may be disposed in the first hole H1. A second low-refractive protection pattern 50c may be disposed in the second hole H2. The low-refractive residual pattern 50r, the first low-refractive protection pattern 50b, and the second low-refractive protection pattern 50c may include the same material as that of the low-refractive grid pattern 50a. The first and second low-refractive protection patterns 50b and 50c may be concave on top surfaces thereof.

On the pixel array region APS, color filters CF1 and CF2 may be disposed between the low-refractive grid patterns 50a. Each of the color filters CF1 and CF2 may have one of blue, green, and red colors. Alternatively, the color filters CF1 and CF2 may include different colors such as cyan, magenta, or yellow. In the image sensor 500 according to some example embodiments, the color filters CF1 and CF2 may be arranged in a Bayer pattern. Alternatively, the color filters CF1 and CF2 may be arranged in one of 2×2 Tetra, 3×3 Nona and 4×4 Hexadeca patterns.

A capping pattern CFR may be disposed on each of the first low-refractive protection pattern 50b and the second low-refractive protection pattern 50c. The capping pattern CFR may include, for example, a photoresist material. The capping pattern CFR may prevent or reduce moisture absorption of the backside vias BVS and may solve step difference between the backside vias BVS.

A second optical black pattern CFB may be disposed on the rear surface 1b of the first substrate 1. The second optical black pattern CFB may include, for example, the same material as that of a blue color filter.

On the pixel array region APS, microlenses ML may be disposed on the color filters CF1 and CF2. The microlenses ML may have their edges that are in contact with and connected to each other. The microlenses ML may constitute an array. The microlenses ML may be called “microlens array.”

On the edge region ER, a lens residual layer MLR may be disposed on the second optical black pattern CFB. The lens residual layer MLR may include the same material as that of the microlenses ML. On the pad region PR, the lens residual layer MLR may have an opening 35 that is formed to expose the backside conductive pad PAD.

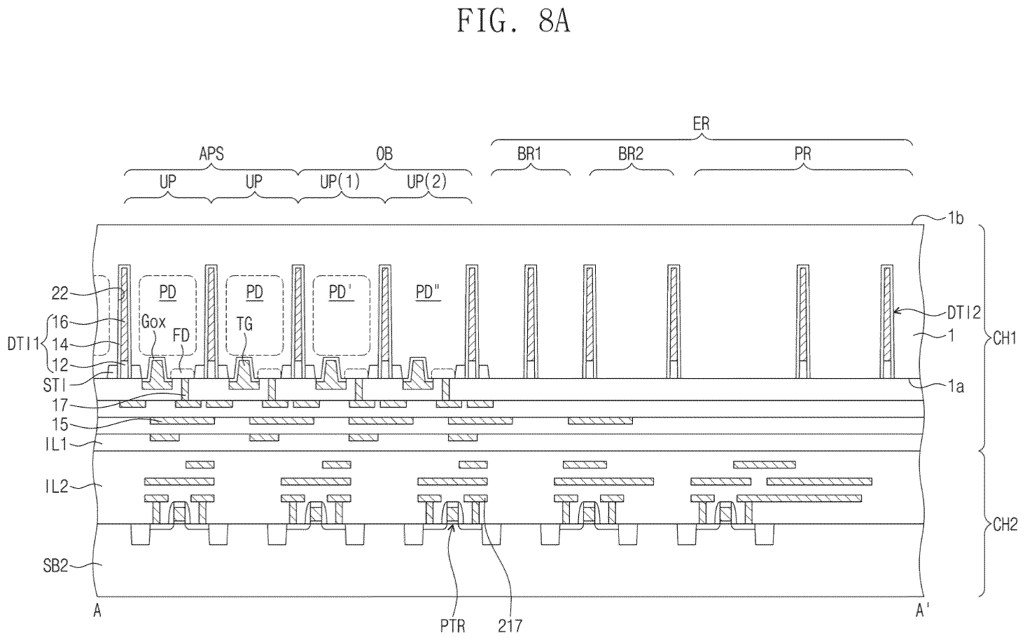

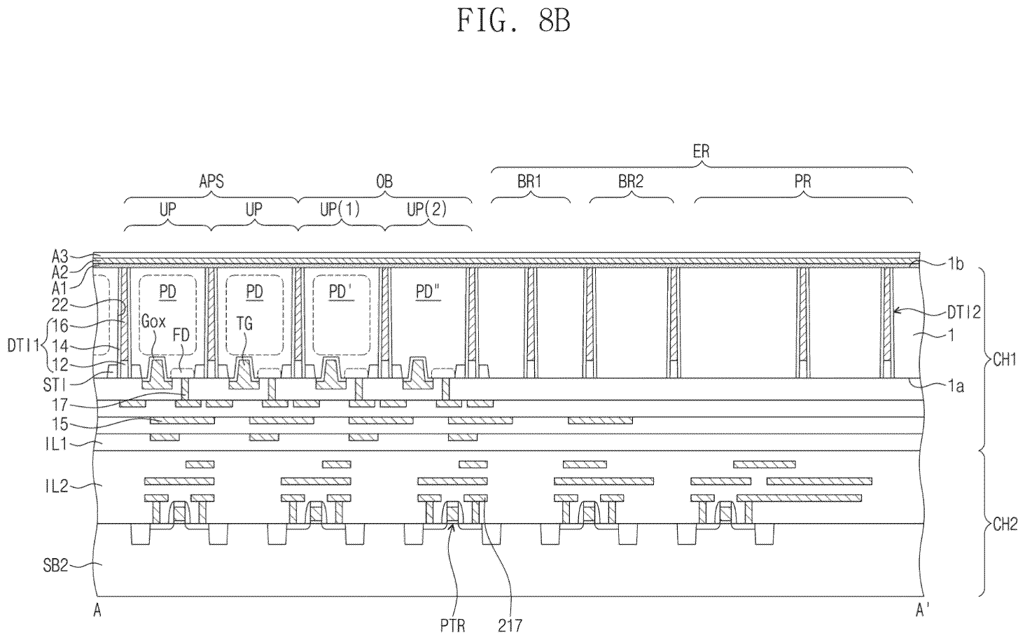

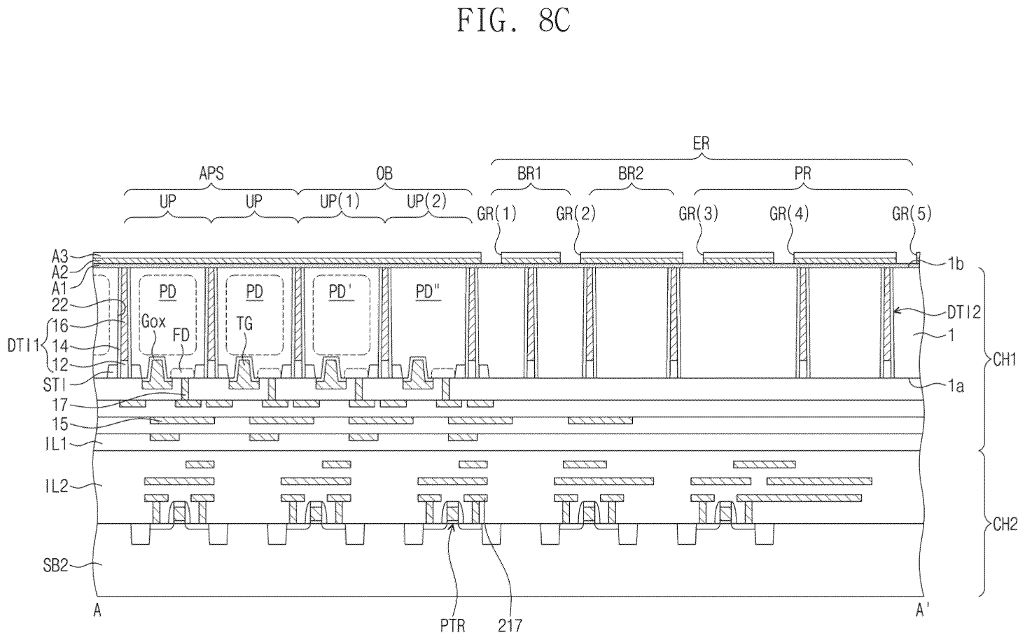

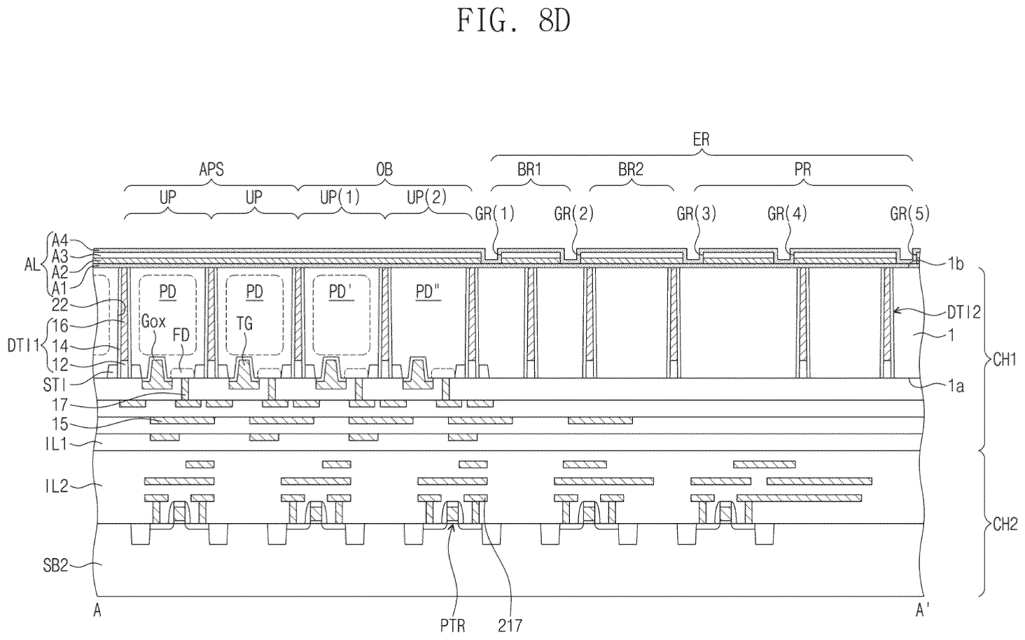

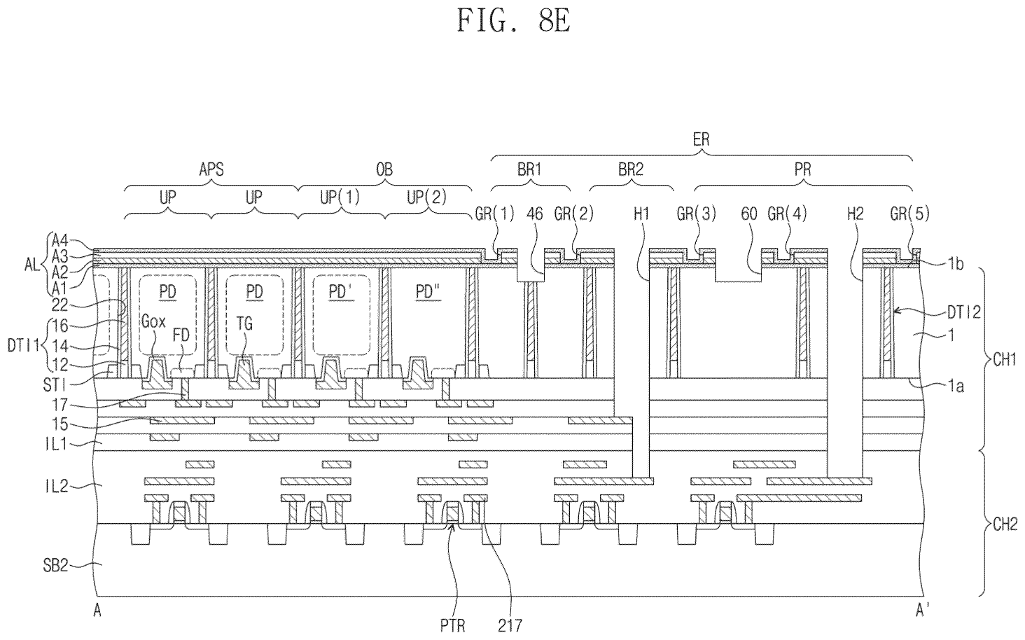

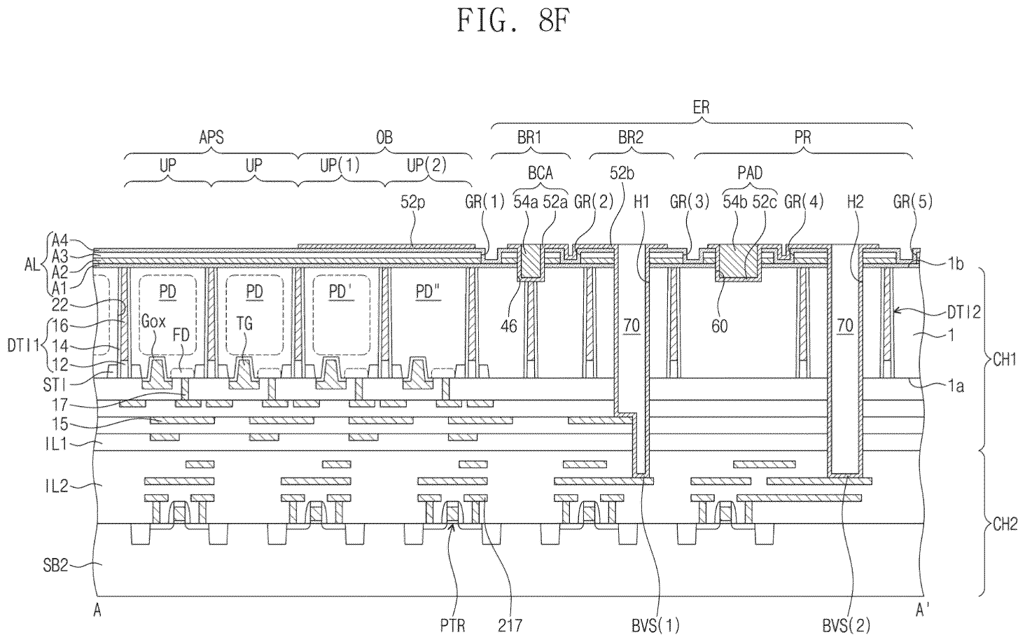

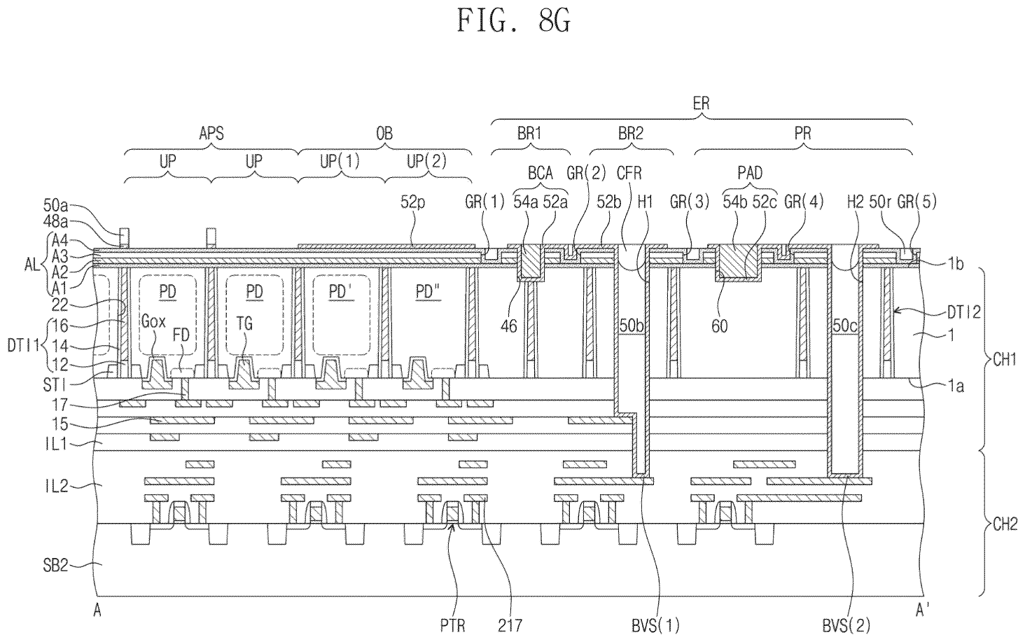

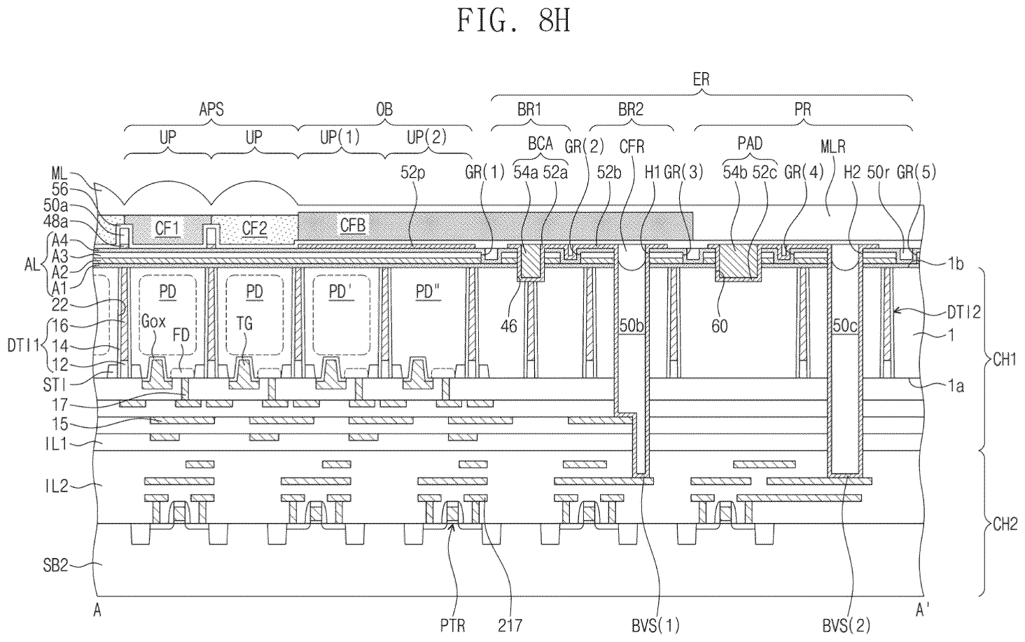

FIGS. 8A to 8H illustrate cross-sectional views showing a method of fabricating an image sensor having the cross-section of FIG. 4.

Referring to FIG. 8A, a first sub-chip CH1 may be fabricated. An ion implantation process may be performed on a first substrate 1 including a pixel array region APS and an edge region ER, thereby forming a photoelectric conversion element PD and a black photoelectric conversion element PD′. The edge region ER may include a contact region BR1, a via region BR2, and a pad region PR. A device isolation part STI may be formed on a front surface 1a of the first substrate 1, thereby defining active sections. The device isolation part STI may be formed by a shallow trench isolation process. The device isolation part STI and a portion of the first substrate 1 may be etched to form deep trenches 22. The deep trenches 22 may limit unit pixels UP on the pixel array region APS and the optical black region OB.

A separation dielectric layer may be conformally formed on the front surface 1a of the first substrate 1, the deep trenches 22 may be filled with a conductive material, and then an etch-back process may be performed to correspondingly form separation conductive patterns 16 in the deep trenches 22. Afterwards, buried dielectric patterns 12 may be formed on the separation conductive patterns 16, and the separation dielectric layer on the front surface 1a may be removed to expose the front surface 1a. Therefore, first and second pixel separation parts DTI1 and DTI2 may be formed at the same time.

Thereafter, an ordinary process may be performed to form a gate dielectric layer Gox, a transfer gate electrode TG, a floating diffusion region FD, first interlayer dielectric layers IL1, first contact plugs 17, and first wiring lines 15 may be formed on the front surface 1a of the first substrate 1.

Referring still to FIG. 8A, a second sub-chip CH2 may be prepared which has a structure discussed with reference to FIG. 4. The first sub-chip CH1 may be turned upside down to allow a rear surface 1b to face upwards. The first sub-chip CH1 may be placed so as to the first interlayer dielectric layer IL1 to contact with the second interlayer dielectric layer IL2, and then a thermocompression process may be performed to bond the first sub-chip CH1 onto the second sub-chip CH2.

Referring to FIG. 8B, a grinding process may be performed on the rear surface 1b of the first substrate 1 depicted in FIG. 8A, and thus a thickness of the first substrate 1 may become reduced to a desired thickness. In this step, the separation conductive patterns 16 of the first and pixel separation parts DTI1 and DTI2 may be exposed. A first dielectric layer A1, a titanium oxide layer A2, and a second dielectric layer A3 may be sequentially stacked on the rear surface 1b of the first substrate 1. The first dielectric layer A1, the titanium oxide layer A2, and the second dielectric layer A3 may each be formed by atomic layer deposition (ALD), chemical vapor deposition (CVD), or physical vapor deposition (PVD). The first dielectric layer A1 may be formed of aluminum oxide to have a first thickness T1 as shown in FIG. 7B. The second dielectric layer A3 may be formed of aluminum oxide to have a third thickness T3 as shown in FIG. 7B. The titanium oxide layer A2 may be formed to have a second thickness T2 as shown in FIG. 7B.

Referring to FIG. 8C, the second dielectric layer A3 and the titanium oxide layer A2 may be partially and sequentially etched to form grooves GR that expose the first dielectric layer A1. Positions and planar shapes of the grooves GR may be the same as or similar to those discussed with reference to FIGS. 3 to 7B.

Referring to FIG. 8D, a third dielectric layer A4 may be conformally formed on the second dielectric layer A3 in a state where the grooves GR are formed. The third dielectric layer A4 may be formed by atomic layer deposition (ALD), chemical vapor deposition (CVD), or physical vapor deposition (PVD). The third dielectric layer A4 may be formed of hafnium oxide. The third dielectric layer A4 may be formed to have a fourth thickness T4 as shown in FIG. 7B. The third dielectric layer A4 may conformally cover sidewalls and bottom surfaces of the grooves GR. Therefore, an antireflection structure AL may be formed.

Referring to FIG. 8E, on the edge region ER, the antireflection structure AL and the first substrate 1 may be partially etched to form a first backside trench 46 and a second backside trench 60. When the first backside trench 46 is formed, the first pixel separation part DTI1 may be partially etched to expose the separation conductive pattern 16 of the first pixel separation part DTI1. On the edge region ER, the antireflection structure AL, the first substrate 1, the first interlayer dielectric layers IL1, and the second interlayer dielectric layer IL2 may be partially etched to form first and second holes H1 and H2. The first and second backside trenches 46 and 60 and the first and second holes H1 and H2 may be formed between the grooves GR.

Referring to FIG. 8F, a conductive layer may be conformally stacked on the rear surface 1b of the first substrate 1, and the conductive layer may be etched to form a first conductive pattern 54a, a second conductive pattern 52c, a backside connection line 52b, a first optical black pattern 52p, and first and second backside vias BVS(1) and BVS(2). When the conductive layer is etched, the third dielectric layer A4 may serve as an etch stop layer. The first and second holes H1 and H2 may be filled with a sacrificial layer 70, a mask pattern (not shown) may be formed to cover a certain area, and then an electroplating or deposition process may be performed to form a first metal pattern 54a and a second metal pattern 54b that respectively fill the first backside trench 46 and the second backside trench 60. Therefore, backside contacts BCA and backside conductive pads PAD may be formed.

Referring to FIG. 8G, a light-shield layer and a low-refractive layer may be sequentially and conformally stacked on the rear surface 1b of the first substrate 1, and the light-shield layer and the low-refractive layer may be etched to form a light-shield grid pattern 48a and a low-refractive grid pattern 50a. When the light-shield layer and the low-refractive layer are etched, the third dielectric layer A4 may serve as an etch stop layer.

Referring to FIG. 8H, a protection layer 56 may be conformally formed on the rear surface 1b of the first substrate 1. An ordinary process may be performed to form color filters CF1 and CF2 and a second optical black pattern CFB. The second optical black pattern CFB may be formed at the same time when a blue color filter is formed. Microlenses ML and a lens residual layer MLR may be formed on the color filters CF1 and CF2 and the second optical black pattern CFB. Subsequently, referring to FIG. 4, on the pad region PR, an opening 35 may be formed in the lens residual layer MLR, exposing the backside conductive pad PAD.

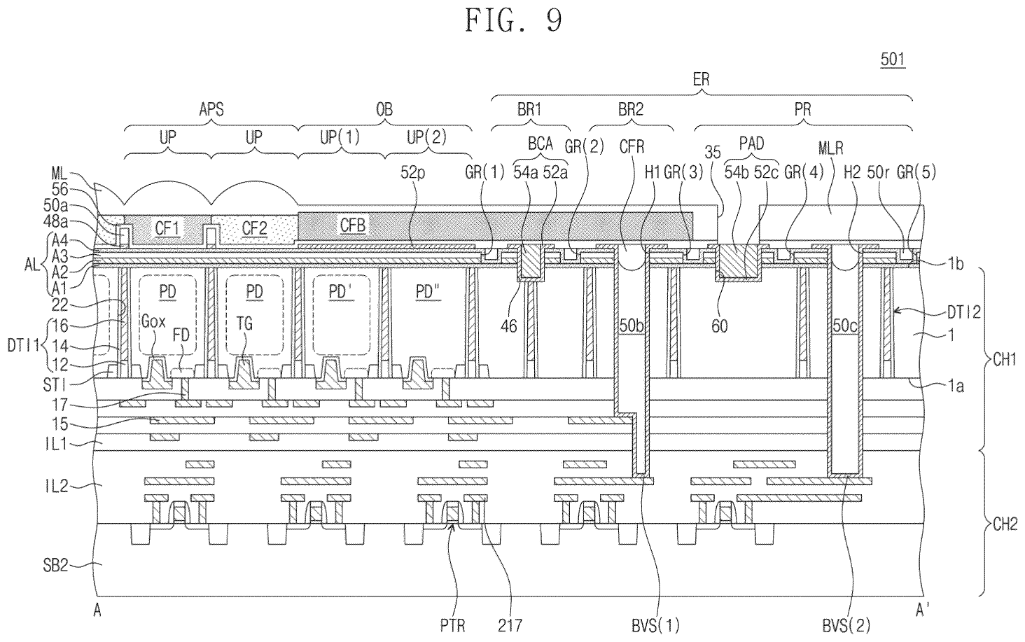

FIG. 9 illustrates a cross-sectional view taken along line A-A′ of FIG. 3.

Referring to FIG. 9, an image sensor 501 according to some example embodiments may not include the backside connection lines 52b of FIG. 4. The backside connection lines 52b may not be disposed in the grooves GR. The backside contacts BCA, the first backside vias BVS(1), the backside conductive pads PAD, and the second backside vias BVS(2) may be electrically insulated from each other without being electrically connected to each other. The grooves GR may be disposed between the backside contacts BCA, the first backside vias BVS(1), the backside conductive pads PAD, and the second backside vias BVS(2). The grooves GR may cut the titanium oxide layer A2, and thus a leakage current or electrical short may be prevented or reduce between the backside contacts BCA, the first backside vias BVS(1), the backside conductive pads PAD, and the second backside vias BVS(2). Other configurations may be identical or similar to those discussed with reference to FIGS. 3 to 7B.

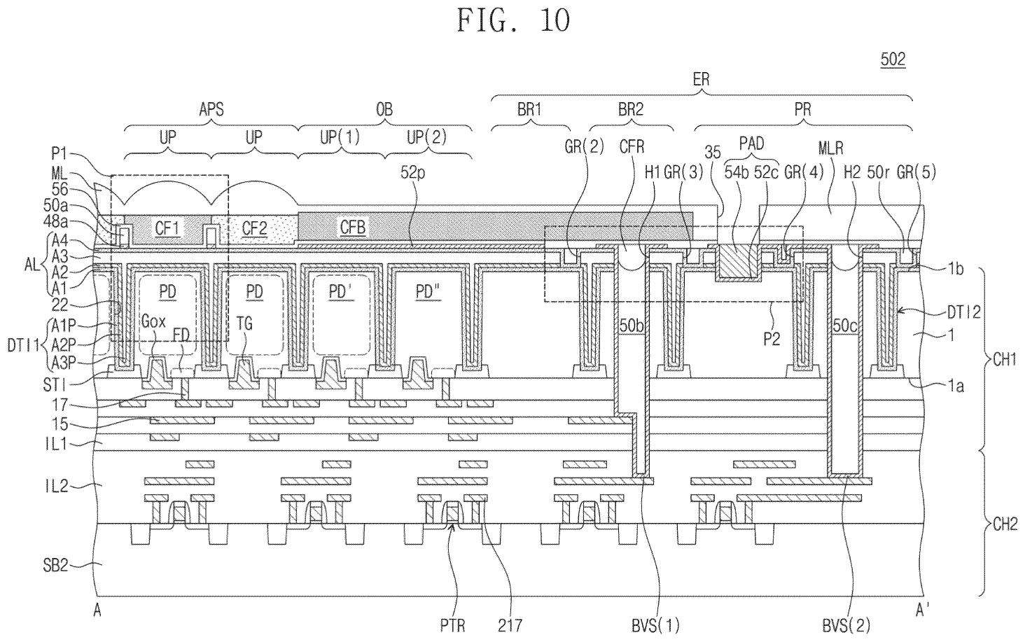

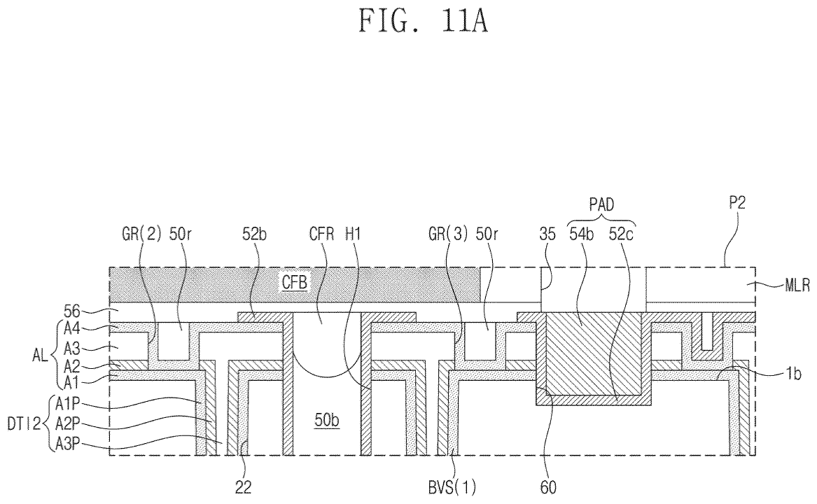

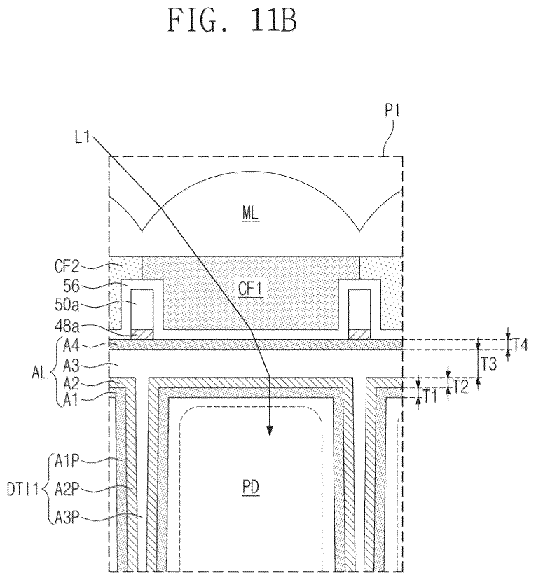

FIG. 10 illustrates a cross-sectional view showing an image sensor according to some example embodiments of the present inventive concepts. FIG. 11A illustrates an enlarged view showing section P1 of FIG. 10. FIG. 11B illustrates an enlarged view showing section P2 of FIG. 10.

Referring to FIGS. 10, 11A, and 11B, an image sensor 502 according to some example embodiments may have a structure in which first and second sub-chips CH1 and CH2 are bonded to each other. The first sub-chip CH1 may be disposed on the second sub-chip CH2. The first sub-chip CH1 may include the first substrate 1.

Each of the first and second pixel separation parts DTI1 and DTI2 may be positioned in the deep trench 22 that is formed directed from the rear surface 1b toward the front surface 1a of the first substrate 1. Each of the first and second pixel separation parts DTI1 and DTI2 may be a backside deep trench isolation (BDTI). A portion of the antireflection structure AL may be inserted into the deep trench 22 to constitute the first and second pixel separation parts DTI1 and DTI2. For example, each of the first and second pixel separation parts DTI1 and DTI2 may include a first dielectric pattern A1P, a titanium oxide pattern A2P, and a second dielectric pattern A3P that sequentially cover an inner wall of the deep trench 22. The second dielectric pattern A3P may fill the deep trench 22. The first dielectric pattern A1P may be formed from a portion of the first dielectric layer A1 of the antireflection structure AL. The titanium oxide pattern A2P may be formed from a portion of the titanium oxide layer A2 of the antireflection structure AL. The second dielectric pattern A3P may be formed from a portion of the second dielectric layer A3 of the antireflection structure AL.

The first dielectric pattern A1P, the second dielectric pattern A3P, and the third dielectric layer A4 may include different materials from each other. For example, the first dielectric layer A1 and the first dielectric pattern A1P may include aluminum, the second dielectric layer A3 and the second dielectric pattern A3P may include silicon oxide, and the third dielectric layer A4 may include hafnium oxide.

The first substrate 1 may have a first refractive index n1, the first dielectric pattern A1P may have a second refractive index n2, the titanium oxide layer A2 may have a third refractive index n3, and the second dielectric pattern A3P may have a fourth refractive index n4. An average, (n2+n3)/2, of the second refractive index n2 and the third refractive index n3 may be less than the first refractive index n1 and greater than the fourth refractive index n4. For example, the first refractive index n1 may range from about 4.0 to about 4.4. The second refractive index n2 may range from about 2.0 to about 3.0. The third refractive index n3 may range from about 2.2 to about 2.8. The fourth refractive index n4 may range from about 1.0 to about 1.9.

As shown in FIG. 11B, the first dielectric layer A1 may have a first thickness T1, the titanium oxide layer A2 may have a second thickness T2, the second dielectric layer A3 may have a third thickness T3, and the third dielectric layer A4 may have a fourth thickness T4. In some example embodiments, the second thickness T2 may be less than the third thickness T3 and greater than each of the first thickness T1 and the fourth thickness T4.

For example, the first thickness T1 may range from about 10 Å to about 100 Å. The second thickness T2 may range from about 100 Å to about 600 Å. The third thickness T3 may range from about 600 Å to about 900 Å. The fourth thickness T4 may range from about 20 Å to about 200 Å.

As shown in FIG. 11B, a relationship between refractive indices and/or thicknesses may allow that the light L1 incident on the microlens ML is refracted and penetrates through a multi-layered structure of the antireflection structure AL and then is appropriately incident on the photoelectric conversion element PD. Accordingly, the image sensor 502 may have increased light-receiving efficiency and sharp image quality.

In addition, in the image sensor 502 according to the present inventive concepts, the antireflection structure AL may include the titanium oxide layer A2. The titanium oxide layer A2 may entirely reduce reflectivity of all colors, and in particular, may further reduce reflectivity of blue light. Accordingly, it may be possible to increase quantum efficiency (QE) of blue color pixels.

The first dielectric pattern A1P and the first dielectric layer A1 may serve as a negative fixed charge layer. Therefore, it may be possible to reduce the dark current and white spots.

The image sensor 502 according to some example embodiments may not include the backside contacts BCA. On the edge region ER, the backside vias BVS and the backside conductive pads PAD may be disposed on the rear surface 1b of the first substrate 1. As shown in FIG. 6, when viewed in plan, the second pixel separation part DTI2 may surround each of the backside vias BVS. The backside vias BVS may include first backside vias BVS(1) and second backside vias BVS(2). Other configurations may be identical or similar to those discussed with reference to FIGS. 3 to 7B.

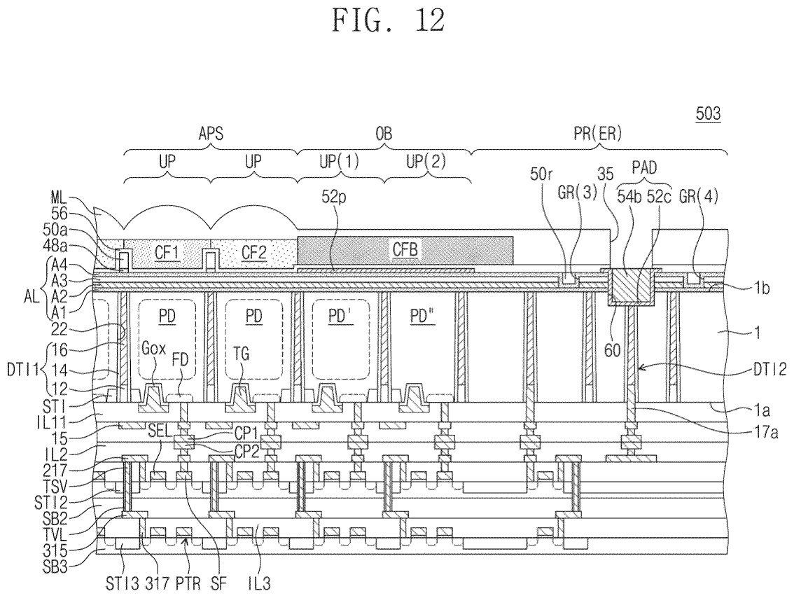

FIG. 12 illustrates a cross-sectional view showing an image sensor according to some example embodiments of the present inventive concepts.

Referring to FIG. 12, an image sensor 503 according to some example embodiments may have a structure in which first to third sub-chips CH1 to CH3 are sequentially stacked. The first sub-chip CH1 may have, for example, an image sensing function.

The first sub-chip CH1 may include transfer gate electrodes TG on the front surface 1a of the first substrate 1 and first interlayer dielectric layers IL1 that cover the transfer gate electrodes TG. The first substrate 1 may be provided in a first device isolation part STI1 that defines active sections. The first sub-chip CH1 may include neither the backside contacts BCA nor the backside vias BVS. The first sub-chip CH1 may further include internal connection contacts 17a. On the edge region ER, at least one of the internal connection contacts 17a may penetrate the buried dielectric pattern 12 of the first pixel separation part DTI1 to connect one of the first wiring lines 15 to the separation conductive pattern 16 of the first pixel separation part DTI1, thereby applying a negative bias voltage to the separation conductive pattern 16. At least another of the internal connection contacts 17a may penetrate the buried dielectric pattern 12 of the second pixel separation part DTI2 below the backside conductive pad PAD to connect one of the first wiring lines 15 to the separation conductive pattern 16 of the second pixel separation part DTI2. A first conductive pad CP1 may be disposed in a lowermost first interlayer dielectric layer IL1. The first conductive pad CP1 may include copper.

The second sub-chip CH2 may include a second substrate SB2, selection gate electrodes SEL, source follower gate electrodes SF, and reset gate electrodes (not shown) that are disposed on the second substrate SB2, and second interlayer dielectric layers IL2 that cover the selection gate electrodes SEL, the source follower gate electrodes SF, and the reset gate electrodes. The second substrate SB2 may be provided therein with a second device isolation part STI2 that defines active sections. The second interlayer dielectric layers IL2 may be provided therein with second contacts 215 and second wiring lines 217. A second conductive pad CP2 may be disposed in an uppermost second interlayer dielectric layer IL2. The second conductive pad CP2 may include copper. The second conductive pad CP2 may be in contact with the first conductive pad CP1. The source follower gate electrodes SF may be correspondingly connected to the floating diffusion regions FD of the first sub-chip CH1.

The third sub-chip CH3 may include a third substrate SB3, peripheral transistors PTR disposed on the third substrate SB3, and third interlayer dielectric layers IL3 that cover the peripheral transistors PTR. The third substrate SB3 may be provided therein with a third device isolation part STI3 that define active sections. The third interlayer dielectric layers IL3 may be provided therein with third contacts 317 and third wiring lines 315. An uppermost third interlayer dielectric layer IL3 may be in contact with the second substrate SB2. A through electrode TSV may penetrate the second interlayer dielectric layer IL2, the second device isolation part STI2, the second substrate SB2, and the third interlayer dielectric layer IL3 to thereby connect one of the second wiring lines 217 to one of the third wiring lines 315. A sidewall of the through electrode TSV may be surrounded by a via dielectric layer TVL. The third sub-chip CH3 may include circuits either for driving one or both of the first sub-chip CH1 and the second sub-chip CH2 or for storing electrical signals generated from one or both of the first sub-chip CH1 and the second sub-chip CH2.

In an image sensor of the present inventive concepts, an antireflection structure may include a titanium oxide layer. The titanium oxide layer may entirely reduce reflectivity of all colors, and in particular, may further reduce reflectivity of blue light. Accordingly, it may be possible to increase quantum efficiency (QE) of color pixels, and in particular, blue color pixels.

In the image sensor of the present inventive concepts, on an edge region, grooves of the antireflection structure may be formed between backside contacts, backside vias, and backside conductive pads, and the grooves may cut the titanium oxide layer. Therefore, a leakage current may be reduced or prevented from being generated due to the titanium oxide layer between the backside contacts, the backside vias, and the backside conductive pads that are adjacent to each other. As a result, it may be possible to prevent or reduce operation errors and to achieve sharp images of the image sensor.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The image sensor (or other circuitry, for example, row driver 1003, row decoder 1002, timing generator 1005, input/output buffer 1008, column decoder 1004, CDS 1006, ADC 1007) may include hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the present inventive concepts have been described in connection with some example embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of FIGS. 3 to 12 may be combined with each other.

What is claimed is:

1. An image sensor, comprising:
a first substrate that has a first surface and a second surface opposite to the first substrate, the first substrate including a pixel array region and an edge region;
an antireflection structure on the second surface;
a pixel separation part in the first substrate, the pixel separation part separating pixels from each other; and
a microlens array on the antireflection structure, the antireflection structure including a first dielectric layer, a titanium oxide layer, a second dielectric layer, and a third dielectric layer that are sequentially stacked, the first dielectric layer, the second dielectric layer, and the third dielectric layer including different materials from each other, and the third dielectric layer, on the edge region, penetrating the second dielectric layer and the titanium oxide layer to contact with the first dielectric layer.

2. The image sensor of claim 1, wherein
the first dielectric layer includes aluminum oxide,
the second dielectric layer includes silicon oxide, and
the third dielectric layer includes hafnium oxide.

3. The image sensor of claim 1, wherein
the first substrate has a first refractive index,
the first dielectric layer has a second refractive index,
the titanium oxide layer has a third refractive index,
the second dielectric layer has a fourth refractive index, and
an average of the second refractive index and the third refractive index is less than the first refractive index and greater than the fourth refractive index.

4. The image sensor of claim 1, further comprising a first contact and a second contact on the second surface of the first substrate on the edge region, and
wherein
the pixel separation part extends to the edge region,
the first contact penetrates a portion of the first substrate to contact with the pixel separation part, and
between the first contact and the second contact, the third dielectric layer penetrates the second dielectric layer and the titanium oxide layer to contact with the first dielectric layer.

5. The image sensor of claim 4, wherein
the pixel separation part includes a separation conductive pattern and a separation dielectric pattern between the separation conductive pattern and the first substrate, and
the first contact is in contact with the separation conductive pattern.

6. The image sensor of claim 4, further comprising:
a first interlayer dielectric layer on the first surface of the first substrate;
a first interconnection layer in the first interlayer dielectric layer;
a second interlayer dielectric layer below the first interlayer dielectric layer;
a second interconnection layer in the second interlayer dielectric layer; and
a second substrate below the second interlayer dielectric layer,
wherein the second contact penetrates the first substrate, the first interlayer dielectric layer, and a portion of the second interlayer dielectric layer to contact with the second interconnection layer.

7. The image sensor of claim 4, wherein
on the edge region, a groove is in the titanium oxide layer and the second dielectric layer,
the first dielectric layer is exposed on a bottom surface of the groove,
the third dielectric layer conformally covers a lateral surface and the bottom surface of the groove, and
the image sensor further comprises a conductive line that connects the first contact to the second contact, the conductive line covering the lateral surface and the bottom surface of the groove.

8. The image sensor of claim 4, wherein
on the edge region, a groove is in the titanium oxide layer and the second dielectric layer,
the first dielectric layer is exposed on a bottom surface of the groove,
the third dielectric layer conformally covers a lateral surface and the bottom surface of the groove, and
when viewed in plan, the groove surrounds the second contact.

9. The image sensor of claim 8, further comprising a substrate isolation part surrounding the second contact between the second contact and the groove and being spaced apart from the second contact on the edge region,
wherein a first interval between the second contact and the substrate isolation part is greater than a second interval between the substrate isolation part and the groove.

10. The image sensor of claim 1, wherein
on the edge region, a groove is in the titanium oxide layer and the second dielectric layer,
the first dielectric layer is exposed on a bottom surface of the groove,
the third dielectric layer conformally covers a lateral surface and the bottom surface of the groove, and
the image sensor further comprises
a low-refractive grid pattern on the pixel array region and on the antireflection structure of the first substrate; and
a low-refractive residual pattern that fills the groove.

11. The image sensor of claim 1, further comprising:
a first interlayer dielectric layer on the first surface of the first substrate;
a first interconnection layer in the first interlayer dielectric layer;
a second interlayer dielectric layer below the first interlayer dielectric layer;
a second interconnection layer in the second interlayer dielectric layer;
a second substrate below the second interlayer dielectric layer;
a conductive pad on the edge region and on the second surface of the first substrate; and
a via on the edge region, the via penetrating the first substrate, the first interlayer dielectric layer, and a portion of the second interlayer dielectric layer to contact with the second interconnection layer,
wherein, between the conductive pad and the via on the edge region, the third dielectric layer penetrates the second dielectric layer and the titanium oxide layer to contact with the first dielectric layer.

12. The image sensor of claim 1, wherein
the pixel separation part is in a deep trench that extends from the second surface toward the first surface, and
a portion of the antireflection structure is inserted into the deep trench to constitute the pixel separation part.

13. The image sensor of claim 11, wherein
the first dielectric layer has a first thickness,
the titanium oxide layer has a second thickness,
the second dielectric layer has a third thickness,
the third dielectric layer has a fourth thickness, and
the second thickness is less than the third thickness and greater than each of the first thickness and the fourth thickness.

14. The image sensor of claim 1, wherein
on the edge region, a groove is in the titanium oxide layer and the second dielectric layer,
the first dielectric layer is exposed on a bottom surface of the groove,
the third dielectric layer conformally covers a lateral surface and the bottom surface of the groove, and
when viewed in plan, the groove surrounds the pixel array region.

15. An image sensor, comprising:
a first substrate that has a first surface and a second surface opposite to the first substrate, the first substrate including a pixel array region and an edge region;
an antireflection structure on the second surface;
a pixel separation part on the first substrate, the pixel separation part separating pixels from each other;
a color filter on the antireflection structure;
a microlens array on the color filter;
a first interlayer dielectric layer on the first surface of the first substrate;
a first interconnection layer in the first interlayer dielectric layer;
a second interlayer dielectric layer below the first interlayer dielectric layer;
a second interconnection layer in the second interlayer dielectric layer;
a second substrate below the second interlayer dielectric layer;
a first contact on the second surface of the first substrate on the edge region; and
a second contact on the edge region, the second contact penetrating the first substrate, the first interlayer dielectric layer, and a portion of the second interlayer dielectric layer to contact with the second interconnection layer,
the antireflection structure including a first dielectric layer, a titanium oxide layer, a second dielectric layer, and a third dielectric layer that are sequentially stacked, the first dielectric layer, the second dielectric layer, and the third dielectric layer including different materials from each other, and between the first contact and the second contact, the third dielectric layer penetrating the second dielectric layer and the titanium oxide layer to contact with the first dielectric layer.

16. The image sensor of claim 15, wherein
the first substrate has a first refractive index,
the first dielectric layer has a second refractive index,
the titanium oxide layer has a third refractive index,
the second dielectric layer has a fourth refractive index, and
an average of the second refractive index and the third refractive index is less than the first refractive index and greater than the fourth refractive index.

17. The image sensor of claim 15, wherein
the pixel separation part includes a separation conductive pattern and a separation dielectric pattern between the separation conductive pattern and the first substrate, and
the first contact is in contact with the separation conductive pattern.

18. An image sensor, comprising:
a first substrate that has a first surface and a second surface opposite to the first substrate, the first substrate including a pixel array region and an edge region;
an antireflection structure on the second surface;
a pixel separation part in the first substrate, the pixel separation part separating pixels from each other; and
a microlens array on the antireflection structure,
the antireflection structure including a first dielectric layer, a titanium oxide layer, a second dielectric layer, and a third dielectric layer that are sequentially stacked, the first dielectric layer, the second dielectric layer, and the third dielectric layer including different materials from each other,
a groove being on the edge region in the titanium oxide layer and the second dielectric layer, the first dielectric layer being exposed on a bottom surface of the groove, the third dielectric layer conformally covering a lateral surface and the bottom surface of the groove, and, when viewed in plan, the groove surrounds the pixel array region.

19. The image sensor of claim 18, wherein
the first dielectric layer has a first thickness,
the titanium oxide layer has a second thickness,
the second dielectric layer has a third thickness,
the third dielectric layer has a fourth thickness, and
the second thickness is less than the third thickness and greater than the first thickness and the fourth thickness.

20. The image sensor of claim 18, further comprising:
a first interlayer dielectric layer on the first surface of the first substrate;
a first interconnection layer in the first interlayer dielectric layer;
a second interlayer dielectric layer below the first interlayer dielectric layer;
a second interconnection layer in the second interlayer dielectric layer;
a second substrate below the second interlayer dielectric layer;
a first contact on the second surface of the first substrate on the edge region; and
a second contact on the edge region, the second contact penetrating the first substrate, the first interlayer dielectric layer and a portion of the second interlayer dielectric layer to contact with the second interconnection layer,
wherein the pixel separation part includes a separation conductive pattern and a separation dielectric pattern between the separation conductive pattern and the first substrate,
wherein the groove is between the first contact and the second contact, and
wherein the first contact is in contact with the separation conductive pattern.
